(19) United States
(12) Patent Application Publication
(10) Pub. No.: US 2005/0146447 A1
(43) Pub. Date: Jul. 7, 2005

(54) Terminal having keyboard with keys variable in arrangement, and method of rearranging keys of keyboard

(75) Inventor: Won-Ju Na, Suwon-si (KR)

Correspondence Address: DILWORTH & BARRESE, LLP, 333 EARLE OVINGTON BLVD., UNIONDALE, NY, 11553, US

(73) Assignee: SAMSUNG ELECTRONICS CO., LTD., Suwon-si (KR)

(21) Appl. No.: 11/016,045

(22) Filed: Dec. 17, 2004

(30) Foreign Application Priority Data
Jan. 5, 2004 (KR) 410/2004

(51) Int. Cl. H03M 11/00; H03K 17/94

(52) U.S. Cl. 341/26

(57) ABSTRACT

A terminal having a keyboard with keys variable in arrangement, and a method for varying the key arrangement are disclosed. The terminal includes a keyboard having a plurality of keys movable in their position, like a puzzle, in a keyboard frame, with at least one of the plurality of keys being detachable from the keyboard frame, a memory for storing a mapping table for mapping code values respectively corresponding to the plurality of keys in the keyboard, and a re-mapping table for re-mapping code values respectively corresponding to the plurality of keys rearranged in the keyboard is provided. A controller recognizes the keys with reference to the mapping table, forms the re-mapping table according to information of key rearrangement when the information of key rearrangement is input, and recognize the keys with reference to the re-mapping table after the re-mapping table is formed.

### PRIORITY

This application claims priority to an application entitled “TERMINAL HAVING KEYBOARD WITH KEYS VARIABLE IN ARRANGEMENT AND METHOD OF REARRANGING KEYS OF KEYBOARD” filed in the Korean Intellectual Property Office on Jan. 5, 2004 and assigned Serial No. 2004-0000410, the contents of which are incorporated herein by reference.

### BACKGROUND OF THE INVENTION

1. Field of the Invention

The present invention relates to a keyboard of a terminal and a method of recognizing keys rearranged in the keyboard, and more particularly to a terminal having a keyboard with keys, which may be rearranged by a user, and a method of rearranging the keys of the keyboard.

2. Description of the Related Art

In general, a keyboard available in a mobile phone or other terminals is provided as a standardized keypad structure having a set key arrangement. As a result, a person who wants to show his or her personality will likely be dissatisfied with the standardized keypad structure. The standardized keypad structure is also not appropriate for companies wishing to differentiate products having the keyboard thereof. Further, user convenience can be improved by allowing variable arrangement of the structure of the keypad.

### SUMMARY OF THE INVENTION

Therefore, the present invention has been made in view of the above problems involved with the related art, and an object of the invention is to provide a terminal having a keyboard with keys, which may be rearranged by a user, and a method of rearranging the keys in the keyboard.

In accordance with one aspect of the present invention, this object is accomplished by the provision of a terminal having a keyboard with keys variable in arrangement, including a keyboard having a plurality of keys movable in their position, like a puzzle, in a keyboard frame, at least one of the plurality of keys being detachable from the keyboard frame; a memory for storing a mapping table for mapping code values respectively corresponding to the plurality of keys in the keyboard, and a re-mapping table for re-mapping code values respectively corresponding to the plurality of keys rearranged in the keyboard; an input portion for inputting information of key rearrangement; and a controller for performing key recognition with reference to the mapping table, for forming the re-mapping table according to the information of key rearrangement when the information of key rearrangement is input through the keyboard, and for performing the key recognition with reference to the re-mapping table after the re-mapping table is formed.

In accordance with another aspect of the present invention, there is provided a method of rearranging keys of a terminal, the terminal including a keyboard having the keys variable in arrangement, and a mapping table for storing code values respectively corresponding to the keys, the method including selecting an item such as “Key arrangement set-up” on a menu screen; displaying a sub-menu screen having a set-up item and a cancellation item shown thereon, such that a user can select the set-up item or the cancellation item, when the item “Key arrangement set-up” is selected; displaying a screen for inputting information of key rearrangement when the set-up item is selected; and forming a re-mapping table according to the information of key rearrangement, followed by performing key recognition with reference to the re-mapping table after the re-mapping table is formed.

### BRIEF DESCRIPTION OF THE DRAWINGS

The above objects and advantages of the present invention will become more apparent by describing in detail preferred embodiments thereof with reference to the attached drawings in which:

FIG. 1 is a diagram illustrating the configuration of a terminal having a keyboard with keys variable in arrangement according to a preferred embodiment of the present invention;

FIGS. 2a to 2e are sample screen displays when performing key rearrangement according to the preferred embodiment of the present invention;

FIGS. 3a to 3c show the keyboard having the keys rearranged according to the preferred embodiment of the present invention;

FIG. 4 is a flow chart of a method of rearranging the keys according to a preferred embodiment of the present invention;

FIG. 5 is a flow chart of a process for recognizing the keys when performing the key rearrangement according to the preferred embodiment of the present invention;

FIG. 6 is an exploded perspective view of a keyboard assembly to which the process for performing the key recognition is applied, when performing the key rearrangement according to the preferred embodiment of the present invention; and

FIG. 7 is a cross sectional view taken along line A-A′ of FIG. 6.

### DETAILED DESCRIPTION OF THE PREFERRED EMBODIMENTS

Now, preferred embodiments of the present invention will be described in detail with reference to the accompanying drawings. In the following description, although a variety of specific elements such as concrete key array sequence are shown, the description of such elements has been made only for a better understanding of the present invention. Accordingly, those skilled in the art will appreciate that the present invention can be implemented without using the above-mentioned specific elements. In the following description of the present invention, a detailed description of known functions and configurations incorporated herein will be omitted to avoid making the subject matter of the present invention unclear.

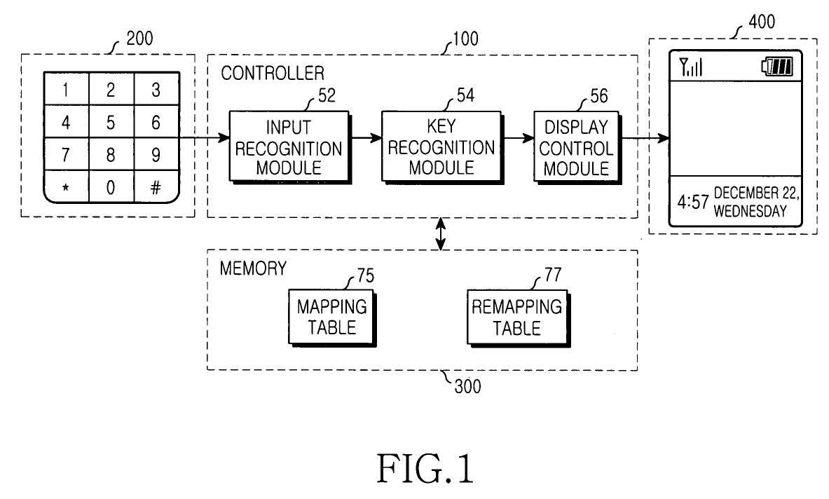

FIG. 1 is a diagram illustrating the configuration of a terminal having a keyboard with keys variable in arrangement according to a preferred embodiment of the present invention.

For purposes of description provided herein, a terminal for a mobile phone shown in FIG. 1 is disclosed as an example of the terminal having the keyboard according to the invention in the specification. One of skill in the art will recognize that the present invention is not restricted to a mobile phone terminal or particular electronic device.

Reference numeral 200 indicates a keyboard of the mobile phone, and reference numeral 400 indicates a display thereof.

The keyboard 200 has a plurality of keys, which are movable in their position, like a puzzle, in a keyboard frame. At least one of the keys can be detached from the keyboard frame to provide space for moving the keys. A user can input information of key rearrangement using the keyboard 200. A dome-type keyboard is a typical type of keyboard that can serve as an embodiment of to the present invention and is used to provide the description herein. One of skill in the art will recognize that the invention is not limited to dome-type keyboards. Furthermore, although the illustrated example allocates only one numeral to one key, this is done for convenience of description, and it is well known in the art that additional or other characters, such as Korean characters or English characters, or other functions may be allocated to the keys.

Reference numeral 300 indicates a memory for storing a mapping table 75 for mapping code values respectively corresponding to the plurality of keys of the keyboard 200, and a re-mapping table 77 for re-mapping code values respectively corresponding to the keys rearranged on the keyboard 200.

Reference numeral 100 indicates a controller comprising three software modules for the present invention. The controller 100 performs key recognition with reference to the mapping table 75, and constitutes the re-mapping table 77 according to the information of key rearrangement inputted through the keyboard, and then recognizes the keys with reference to the re-mapping table 77, after the re-mapping table 77 is constituted.

Specifically, the controller 100 comprises an input recognition module 52, a key recognition module 54, and a display control module 56. The input recognition module 52 serves to recognize the code value of the key in the keyboard 200, which is pressed by the user. The key recognition module 54 serves to recognize the re-mapped code value corresponding to the keys rearranged in the keyboard. The display control module 56 serves to send the re-mapped code value to the display 400, allowing the numeral allocated to the key rearranged in the keyboard to be displayed on a screen of the terminal.

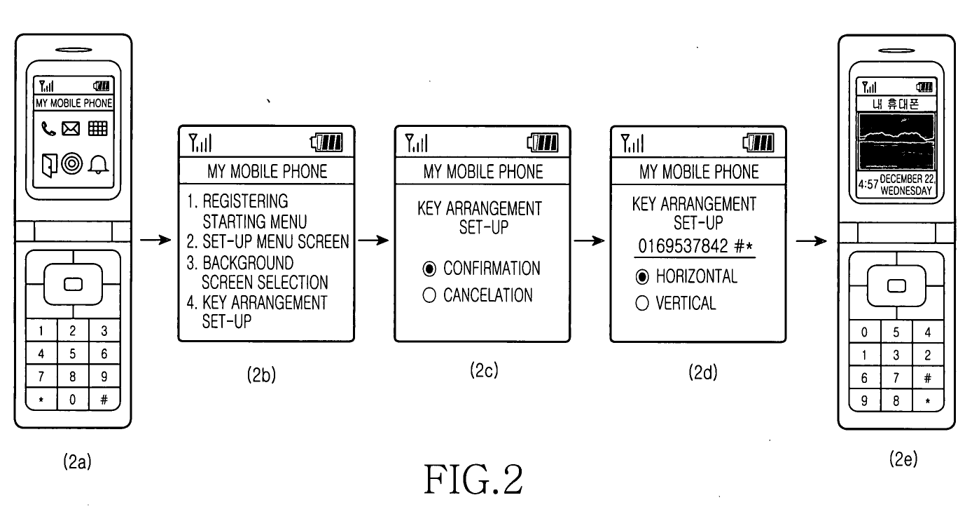

FIGS. 2a to 2e are sample screen displays of the terminal when performing the key rearrangement according to the preferred embodiment of the present invention.

FIG. 2a shows a state of the display of the terminal and the keyboard before the keys are rearranged. It is assumed that a plurality of icons corresponding to functions of the mobile phone are shown on the display. In the illustrated example, the numeral keys, 0 to 9, and symbol keys, # and *, are arranged in a 3×4 matrix keyboard.

FIG. 2b shows a menu screen including a key rearrangement item shown on the display of the mobile phone. The menu screen can be displayed by selecting an associated icon on the display of FIG. 2a.

FIG. 2c shows a sub-screen displayed when the user selects an item “4. Key arrangement set-up” in FIG. 2b. This sub-screen allows the user to determine whether the user has rearranged the keys (Set-up), or whether the user has returned the rearranged keys to an initial arrangement state of the keys (Cancellation).

FIG. 2d shows a sub-screen for inputting predetermined information of key rearrangement, which is displayed when the user selects an item “Set-up” on the sub-screen of FIG. 2c. Here, the information of key rearrangement includes a sequence of key arrangement and a direction of key arrangement. In the illustrated example, the numeral keys, 0 to 9, and symbol keys, # and *, are arranged in a 3×4 matrix keyboard. In the illustrated example, the numeral keys and symbol keys indicating 0, 1, 6, 9, 5, 3, 7, 8, 4, 2, #, and * are arranged in a horizontal direction in the 3×4 matrix keyboard from a first row to a forth row in this order, with 0, 5, and 4 being the keys at the top of each of the three columns shown in FIG. 2e to be described later. Here, key movement is performed in a manner akin to the user playing with a puzzle. Although the term “key movement” is used for the convenience of the description, the term “key movement” means movement of key cap parts. The key cap parts correspond to the components that are typically extruded and mounted above an outer surface of a dome sheet or dome switch, and are separate from the dome sheet or dome switch.

FIG. 2e shows the display and the keyboard of the mobile phone immediately after the rearrangement of the keys.

Although not shown in the drawings, it will be recognized that the keys of a terminal using a touch pad can be rearranged by performing the same method described in regard to FIGS. 2b to 2d. In this case, the key movement is not carried out by the user, but is displayed on the screen of the terminal after, or while, being changed by the terminal.

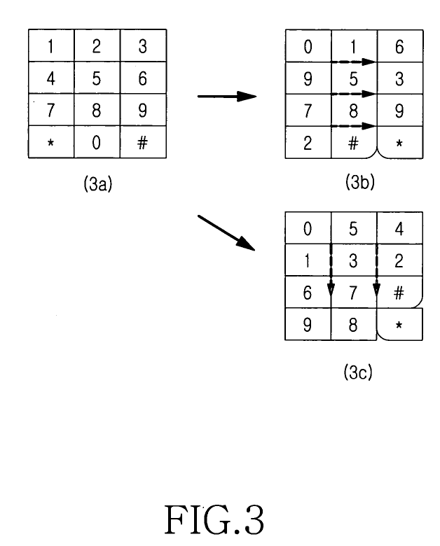

FIGS. 3a to 3c show the keyboard with the keys rearranged according to the preferred embodiment of the present invention.

FIG. 3a shows a key array in the 3×4 matrix keyboard having a standardized key array. FIG. 3c shows the key array rearranged in the horizontal direction. FIG. 3c shows the result of rearranging the keys in the horizontal direction as described above in FIGS. 2d and 2e. FIG. 3b shows the key array rearranged in the vertical direction from the state shown in FIG. 3a. In this case, though data for the sequence of the key rearrangement is the same as that of the case shown in FIG. 2d, since the direction of the key rearrangement is different from that of the case shown in FIG. 2d, the result is also different from that of the case shown in FIG. 2d. Meanwhile, it should be understood that arrows illustrated by dotted lines in FIGS. 3b and 3c indicate the rearrangement in the horizontal direction and in the vertical direction on the drawings, for the convenience of understanding.

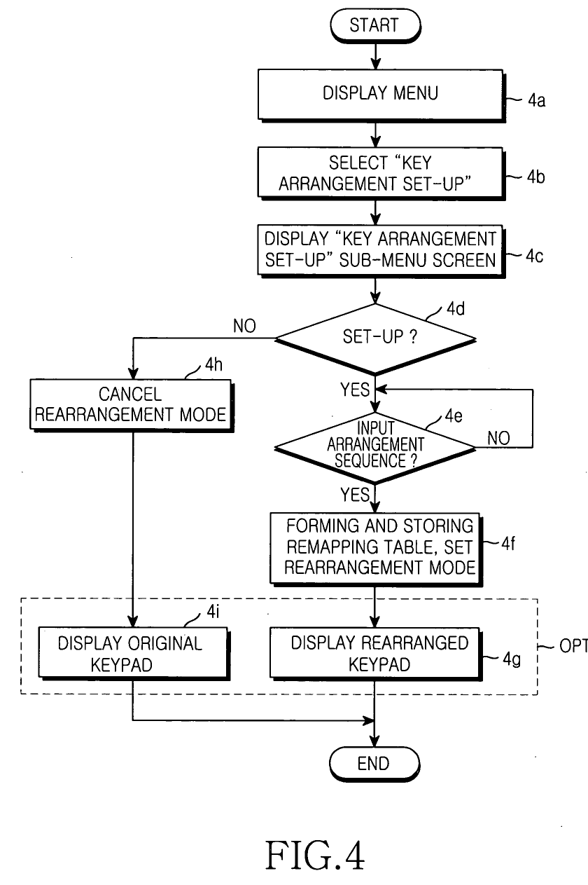

FIG. 4 is a flow chart of a method of rearranging the keys according to a preferred embodiment of the present invention.

At step 4a, the controller 100 controls the display of the menu-screen shown in FIG. 2b, as described above. When the controller 100 detects the selection of an item such as item “Key arrangement set-up” by the user at step 4b, the controller 100 controls the display of the sub-menu screen for “Key arrangement set-up” as shown in FIG. 2c at step 4c. At step 4d, the controller 100 determines whether the user selects the item “Set-up.” If the user selects the item “Set-up,” the controller 100 detects whether the user inputs the sequence of key rearrangement. If the user inputs the sequence of key rearrangement, the controller 100 creates and stores the re-mapping table, and then sets a rearrangement mode at step 4f. Via the rearrangement mode, the controller 100 recognizes the keys not by referencing the mapping table, but by referencing the re-mapping table, when an input operation is performed using the rearranged keys.

If the user does not select the item “Set-up” at step 4d, the controller releases the key rearrangement mode at step 4h. Accordingly, when the input operation is performed using the keys, the controller recognizes the keys with reference to the mapping table.

It will be recognized that steps 4g and 4i, shown in a dotted line block OPT of FIG. 4, are performed when the keyboard is embodied on the screen of the display 400, using the touch screen. That is, when the key rearrangement mode is released at step 4h, an initial keyboard arrangement is shown on the screen of the display 400 at step 4i. Furthermore, if the key rearrangement mode is set at step 4f, the rearranged keys are shown on the screen of the display 400 at step 4g.

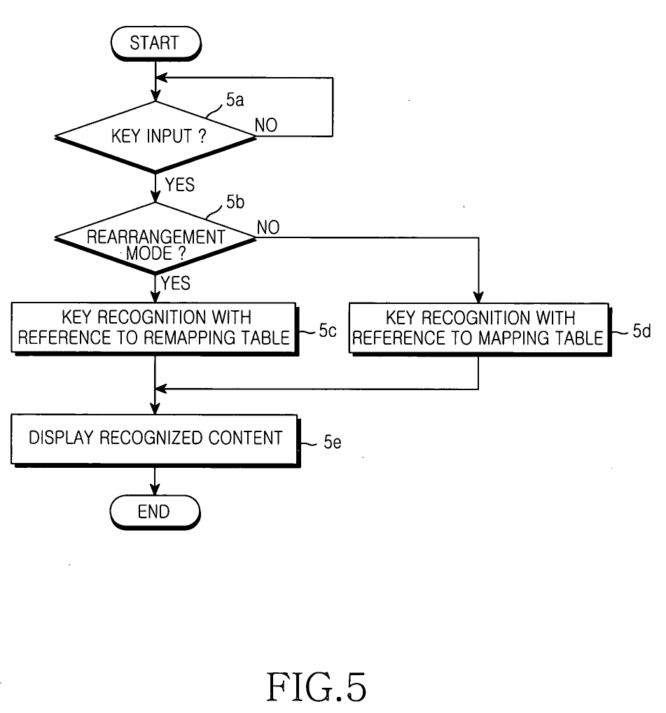

FIG. 5 is a flow chart of a process for recognizing the keys when performing the key rearrangement according to the preferred embodiment of the present invention. At step 5a, the controller 100 detects whether the input operation is performed using the keys. If the input operation is performed, at step 5b, the controller 100 detects whether the rearrangement mode is set. If the rearrangement mode is set, the controller 100 recognizes the keys with reference to the re-mapping table at step 5c. On the contrary, if the rearrangement mode is not set, the controller 100 recognizes the keys with reference to the mapping table at step 5d. At step 5e, the controller 100 controls display of recognized content according to the content of the key recognition.

The key recognition performed with reference to the re-mapping table at step 5c will be specifically described in detail with reference to the example tables below.

Table 1 shows an example of code values corresponding to the keys in an inherent key arrangement.

TABLE 1

| | Numeral key | | | | | | | | | | | |
|---|---|---|---|---|---|---|---|---|---|---|---|---|
| | 1 | 2 | 3 | 4 | 5 | 6 | 7 | 8 | 9 | 0 | * | # |
| Code | 16 | 17 | 18 | 19 | 20 | 21 | 22 | 23 | 24 | 25 | 26 | 27 |

Table 2 shows an example of re-mapped code values.

TABLE 2

| | Numeral key | | | | | | | | | | | |
|---|---|---|---|---|---|---|---|---|---|---|---|---|
| | 0 | 5 | 4 | 1 | 3 | 2 | 6 | 7 | # | 9 | 8 | * |
| Code | 16 | 17 | 18 | 19 | 20 | 21 | 22 | 23 | 24 | 25 | 26 | 27 |

Table 3 shows an example of inherent code values of the keys. For the convenience of understanding, Table 3 shows the code values recognized or transmitted to the respective modules included in the controller or the display 400 shown in FIG. 1.

TABLE 3

| | | | | | | | | | | | | |
|---|---|---|---|---|---|---|---|---|---|---|---|---|
| Input | 16 | 17 | 18 | 19 | 20 | 21 | 22 | 23 | 24 | 25 | 26 | 27 |
| recognition | | | | | | | | | | | | |
| module | | | | | | | | | | | | |
| Key | 16 | 17 | 18 | 19 | 20 | 21 | 22 | 23 | 24 | 25 | 26 | 27 |
| recognition | ↓ | ↓ | ↓ | ↓ | ↓ | ↓ | ↓ | ↓ | ↓ | ↓ | ↓ | ↓ |
| module | 25 | 20 | 19 | 16 | 18 | 17 | 21 | 22 | 26 | 24 | 23 | 27 |
| Display | 25 | 20 | 19 | 16 | 18 | 17 | 21 | 22 | 26 | 24 | 23 | 27 |
| control | | | | | | | | | | | | |
| module | | | | | | | | | | | | |
| Display | 0 | 5 | 4 | 1 | 3 | 2 | 6 | 7 | # | 9 | 8 | * |

With reference to FIGS. 1-2, although a cursor (preferably in the shape of a hand) may be positioned on the numeral key ‘5’ on the keyboard 200, the numeral shown on the display 400 is ‘3.’ This is because the re-mapping is performed according to the present invention. The principle of displaying the numeral ‘3’ on the screen of the display 400 when the user presses down the key indicating ‘5’ will be described as follows.

When the user presses down the key indicating ‘5,’ the input recognition module 52 recognizes a code value ‘20’ corresponding to the key indicating ‘5’ in Table 1, and sends the code value ‘20’ to the key recognition module 54. The key recognition module 54 recognizes the previously re-mapped values, and, by referencing Table 2, sends a code value ‘18’ corresponding to the numeral ‘3’ to the display control module to display the numeral ‘3’ on the screen of the display 100.

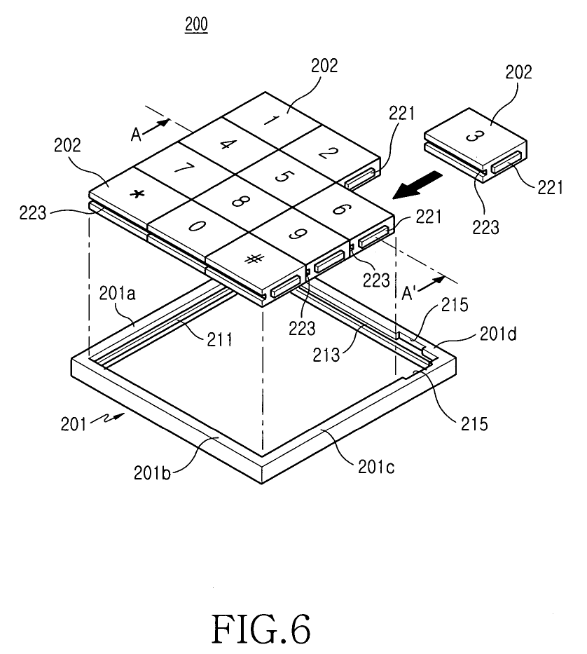

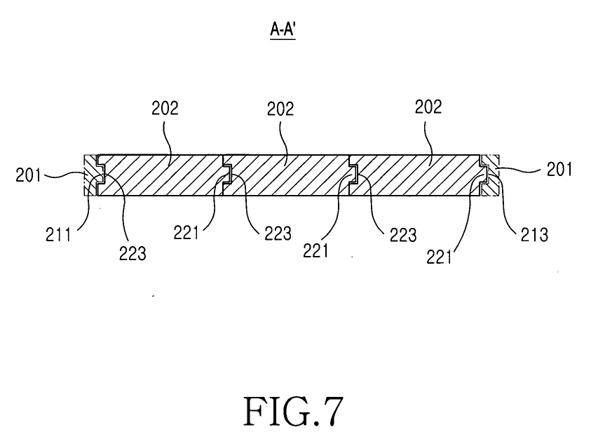

The keyboard 200 having the keys variable in arrangement as described above will be described in detail with reference to FIGS. 6 and 7. FIG. 6 is an exploded perspective view of a keyboard assembly to which the process for performing the key recognition is applied, when performing the key rearrangement according to the preferred embodiment of the present invention, and FIG. 7 is a cross sectional view taken along line A-A′ of FIG. 6.

It should be noted that FIGS. 6 and 7 show a keyboard frame 201 and a plurality of key caps 202, and do not show components, such as dome switches, for generating and sending electrical signals among other standard keyboard components.

The keyboard frame 201 typically has a rectangular shape with four sides thereof closed by four frame pieces, respectively, and with upper and lower surfaces thereof opened. Within the keyboard frame 201 a plurality of key caps 202 are provided such that the plurality of key caps 202 may slide inside the keyboard frame. For the convenience of description, the four frame pieces are defined as first, second, third and fourth frame pieces 201a, 201b, 201c, and 201d.

Among the first to fourth frame pieces, 201a, 201b, 201c, and 201d, the first frame piece 201a and the second frame piece 201b adjoin each other at one end thereof, are provided with first guide ribs 211 extended in a lengthwise direction, respectively, and protrude inward towards the keyboard frame 201. The third and fourth frame pieces 201c and 201d are provided at inner surfaces thereof with first guide holes 213 extended in a lengthwise direction, respectively, depressed from the inner surfaces of the third and fourth frame pieces 201c and 201d. Furthermore, the third and fourth frame pieces 201c and 201d are provided with mounting holes 215 respectively defined on upper edges near the corner where the third and fourth frame pieces 201c and 201d adjoin each other. Each of the mounting holes 215 allows a portion of each of the first guide holes 213 to be exposed to an upper surface of the keyboard frame 201.

According to the drawings, the keyboard frame 201 is shown as an independent component. However, it is clear that the keyboard frame 201 can be integrally formed with a body of the keyboard or with a body of a variety of terminals, like the terminal of the mobile phone.

The plurality of key caps 202 is provided in the keyboard frame 201 such that the plurality of key caps 202 may slide inside the keyboard frame while the key caps adjoin each other. Each of the key caps 202 is defined with second guide ribs 221 protruded, respectively, on a pair of outer surfaces of the key cap 202 adjoining each other, and with second guide holes 223 depressed, respectively, on a pair of other outer surfaces thereof adjoining each other.

Each of the second guide ribs 221 of one of the key caps is slidably matched to the first guide hole 223 of the keyboard frame 201 or to the second guide hole 223 of an other key cap 202. The second guide hole 223 is slidably matched to the first guide rib 221 of the keyboard frame 201 or to the second guide rib 221 of an other key cap 202.

Accordingly, the key cap 202 may slide inside the keyboard frame 201 by the construction of the first and second guide ribs 211 and 221, and of the first and second guide holes 213 and 223.

Here, it is apparent that a space for allowing the key caps 202 to slide inside the keyboard frame 201 should be provided. In order to provide the space for allowing the key caps 202 to slide inside the keyboard frame 201, at least one of the key caps 202 must be detached from the keyboard frame 201 in the present embodiment. That is, the third and fourth frames 201c and 201d of the keyboard frame 201 are defined with the mounting holes 215 thereon to adjoin each other, so that at least one of the key caps 202 can be detached therefrom. In order to allow one of the key caps 202 to be detached from the keyboard frame 201, each of the mounting holes 215 has a shape corresponding to the second guide rib 221 of the key caps 202.

Meanwhile, though not shown in the drawings, in order to allow one of the key caps 202 to be detached from the keyboard frame 201, a portion of each of the first guide ribs 211 can be removed. That is, a portion of each of the first guide ribs 211 is removed, by an amount to allow one of the key caps 202 to be detached from the keyboard frame 201, near to the edges thereof where the first and second frames 201a and 201b adjoin each other. In this case, it is not necessary to define the mounting holes 215.

Furthermore, considering that the mounting holes 215 are formed to provide the space for allowing the key caps 202 to slide in the keyboard frame 201, there may be defined additional space (not shown) at an outer side of the keyboard frame 201. That is, the keyboard frame 201 is formed at one end thereof with the additional space for the one of the key caps 202 to move thereto, thereby providing space to allow other key caps to slide. As such, when the additional space for allowing the key caps to move thereto, it is apparent that additional guide ribs and guide holes must be formed in order to guide the sliding of the key caps.

With the keyboard structured as described above, one of the key caps 202 is detached from the keyboard frame 201, forming a predetermined space, so that the user may set the desired arrangement of the keys by slidably moving other key caps sequentially.

As apparent from the description, according to the present invention, there is provided advantageous keyboard of the present invention that allows the user to change the key arrangement as they desire, satisfying the user's tendency or desire to use the keyboard, thereby enhancing satisfaction with the product having the keyboard according to the invention. Furthermore, the terminal favorably allows the user to express their personality when the keys have pictures or colors on the surfaces thereof. For instance, when puzzle pieces are painted on the surfaces of the key, the user may play with the puzzle.

Although the preferred embodiments of the present invention have been disclosed for illustrative purposes, those skilled in the art will appreciate that various modifications, additions and substitutions are possible, without departing from the scope and spirit of the invention, as disclosed in the accompanying claims.

1. A terminal having a keyboard comprising:
a keyboard having a plurality of keys movable in their position, that can be variably arranged, in a keyboard frame, with at least one of the plurality of keys being detachable from the keyboard frame;
a memory for storing a mapping table for mapping code values respectively corresponding to the plurality of keys in the keyboard and a re-mapping table for re-mapping code values respectively corresponding to the plurality of keys rearranged in the keyboard; and
a controller for recognizing the keys with reference to the mapping table, for forming the re-mapping table according to information of key rearrangement when the information of key rearrangement is input, and for recognizing the keys with reference to the re-mapping table after the re-mapping table is formed.

2. The terminal as set forth in claim 1, wherein the code values are fixed values corresponding to respective points of coordinates in an m×n matrix structure.

3. The terminal as set forth in claim 1, wherein the memory is a flash memory.

4. A terminal having a keyboard displayed on a screen thereof, comprising:
a memory for storing a mapping table for mapping code values respectively corresponding to the plurality of keys in the keyboard and a re-mapping table for re-mapping code values respectively corresponding to the plurality of keys rearranged in the keyboard; and
a controller for recognizing the keys with reference to the mapping table, for forming the re-mapping table according to information of key rearrangement when the information of key rearrangement is input, for displaying a key array rearranged according to the information of key rearrangement on the screen of the terminal, and for recognizing the keys with reference to the re-mapping table after the re-mapping table is formed.

5. The terminal as set forth in claim 4, wherein the code values are fixed values corresponding to respective points of coordinates in an m×n matrix structure.

6. The terminal as set forth in claim 4, wherein the memory is a flash memory.

7. The terminal as set forth in claim 1, wherein the keyboard comprises:
a rectangular shaped keyboard frame closed by four frame pieces;
first guide ribs protruded and extended in a lengthwise direction, respectively, on inner surfaces of a pair of adjoining frame pieces;
first guide holes depressed and extended in the lengthwise direction, respectively, on inner surfaces of the other pair of adjoining frame pieces; and
a plurality of key caps, each having second guide ribs corresponding in shape to the first guide holes and extended in the lengthwise direction, respectively, on a pair of adjoining outer surfaces of the key cap, and second guide holes corresponding in shape to the first guide ribs and extended in the lengthwise direction, respectively, on the other pair of adjoining outer surfaces of the key cap, so that the plurality of key caps may slide in the keyboard frame when one key cap is removed.

8. The terminal as set forth in claim 7, wherein the keyboard frame is integrally formed with the terminal.

9. The terminal as set forth in claim 8, wherein as each of the key cap slides in the keyboard frame, the second guide ribs and the second guide holes formed on the outer surface of the key cap are respectively matched to the first guide ribs and the first guide holes or to the second guide ribs and the second guide holes of a key cap adjacent to the sliding key cap.

10. The terminal as set forth in claim 9, wherein the keyboard further comprises a pair of mounting holes extending on an upper surface of the keyboard, respectively, and exposing the first guide holes to the upper surface of the keyboard frame.

11. The terminal as set forth in claim 10, wherein each of the mounting holes has a size and a shape to allow the second guide rib to pass therethrough.

12. A method of rearranging keys of a terminal, the terminal including a keyboard having the keys variable in arrangement, and a mapping table for storing code values respectively corresponding to the keys, the method comprising:
selecting a key arrangement set-up item on a menu screen;
displaying a sub-menu screen having a set-up item and a cancellation item shown thereon such that a user can select the set-up item or the cancellation item, when the key arrangement set-up item is selected;
displaying a screen for inputting information of key rearrangement when the set-up item is selected on the sub-menu screen; and
forming a re-mapping table according to the information of key rearrangement, followed by performing key recognition with reference to the re-mapping table.

13. A method of rearranging keys of a terminal, the terminal enabling key input with a keyboard displayed on a screen, and including a mapping table for storing code values respectively corresponding to the keys of the keyboard, the method comprising:
selecting a key arrangement set-up item on a menu screen;
displaying a sub-menu screen having a set-up item and a cancellation item shown thereon such that a user can select the set-up item or the cancellation item, when the key arrangement set-up item is selected;
displaying a screen for inputting information of key rearrangement when the set-up item is selected on the sub-menu screen; and
forming a re-mapping table according to the information of key rearrangement, followed by displaying key array according to the information of key rearrangement on the screen of the terminal, and performing a process of key recognition with reference to the re-mapping table after the re-mapping table is formed.

14. The method as set forth in claim 13, further comprising:
detecting whether an input operation is performed using the keys;
detecting whether a key rearrangement mode is set, when the input operation is performed using the keys; and
performing key recognition with reference to the re-mapping table if the key rearrangement mode is set, or performing key recognition with reference to the mapping table if the key rearrangement mode is not set.
